(19) United States
(12) Patent Application Publication
(10) Pub. No.: US 2026/0244090 A1
(43) Pub. Date: Aug. 20, 2026

(54) EUV MASK

(71) Applicant: ASML Netherlands B.V., Veldhoven (NL)

(72) Inventors: Wenjie JIN, Eindhoven (NL); John Martin MCNAMARA, Veldhoven (NL)

(73) Assignee: ASML Netherlands B.V., Veldhoven (NL)

(21) Appl. No.: 19/159,841

(22) PCT Filed: Feb. 9, 2024
(86) PCT No.: PCT/EP2024/053319

§ 371 Date: Aug. 26, 2025

(30) Foreign Application Priority Data
Mar. 14, 2023 (EP) 23161667.3
May 23, 2023 (EP) 23174812.0

(51) Int. Cl. G03F 1/24; G03F 1/26; H10P 76/40

(52) U.S. Cl. CPC G03F 1/24; G03F 1/26; H10P 76/4085

(57) ABSTRACT

Disclosed herein is a mask for patterning radiation in a lithographic apparatus, the mask comprising: a patterning surface arranged to impart a pattern on radiation; and waveguide structures arranged on the patterning surface; wherein the patterning surface comprises: a first reflective region; and a second reflective region arranged so that the radiation that reflects off the second reflective region is phase shifted relative to the radiation that reflects off the first reflective region.

### CROSS-REFERENCE TO RELATED APPLICATIONS

This application claims priority of EP Application Serial No. 23161667.3 which was filed on 14 Mar. 2023, and EP Application Serial No. 23174812.0 which was filed on 23 May 2023, which are incorporated herein in its entirety by reference.

### FIELD

The present invention relates to masks for EUV radiation. The masks according to embodiments have improved imaging properties over known masks for EUV radiation. This may both improve the manufacture of features by an EUV lithographic process and also reduce the required dose of EUV radiation.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} * \frac{λ}{N A} \qquad ( 1 )$$

where λ is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

A lithographic apparatus includes a patterning device (e.g., a mask or a reticle). Radiation is provided through, or reflected off, the patterning device to form an image on a substrate.

There is general desire to improve on known masks for use with EUV radiation.

### SUMMARY OF THE INVENTION

According to a first aspect of the invention, there is provided a mask for patterning radiation in a lithographic apparatus, the mask comprising: a patterning surface arranged to impart a pattern on radiation; and waveguide structures arranged on the patterning surface; wherein the patterning surface comprises: a first reflective region; and a second reflective region arranged so that the radiation that reflects off the second reflective region is phase shifted relative to the radiation that reflects off the first reflective region.

According to a second aspect of the invention, there is provided a lithographic apparatus comprising the mask according to the first aspect.

According to a third aspect of the invention, there is provided a method of designing a reflective mask for patterning radiation in a lithographic apparatus, wherein the mask comprises first and second reflective regions for imparting different phase shifts on illuminating radiation and the mask comprises waveguide structures on the first and/or second reflective regions, the method comprising: determining a combined width of the first and second reflective regions of the mask in dependence on a user-defined pitch of features to be printed by radiation patterned by the mask; determining the material and location of each waveguide structure; and determining the dimensions of each waveguide structure, the width of the first reflective region and the width of the second reflective region such that the radiation patterned by the mask has a desired characteristic.

According to a fourth aspect of the invention, there is provided a method for performing lithography, the method comprising projecting a radiation beam through a low pressure environment onto a substrate in an exposure operation; wherein the radiation beam reflects off a mask located in the low pressure environment; and the mask is according to the first aspect.

According to a fifth aspect of the invention, there is provided a mask for patterning radiation in a lithographic apparatus, the mask comprising a patterning surface arranged to impart a pattern on radiation; wherein: the patterning surface comprises a first reflective region and a second reflective region; the second reflective region comprises an embedded phase shifting structure that is arranged so that the radiation that reflects off the second reflective region is phase shifted relative to the radiation that reflects off the first reflective region; the first reflective region comprises a main region and at least one sub-region at an end of the first reflective region; the at least one sub-region of the first reflective region has different reflective properties to the main region of the first reflective region; the second reflective region comprises a main region and at least one sub-region at an end of the second reflective region; and the at least one sub-region of the second reflective region has different reflective properties to the main region of the second reflective region.

According to a sixth aspect of the invention, there is provided a lithographic apparatus comprising the mask according to the fifth aspect.

According to a seventh aspect of the invention, there is provided a method for performing lithography, the method comprising projecting a radiation beam through a low pressure environment onto a substrate in an exposure operation; wherein the radiation beam reflects off a mask located in the low pressure environment; and the mask is according to the first aspect.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 is a more detailed view of the lithographic apparatus;

FIG. 3a schematically depicts a known EUV mask;

FIG. 3b schematically depicts an aerial image of a known EUV mask;

FIG. 4 schematically depicts an EUV mask according to a first embodiment of the invention;

FIG. 5 schematically depicts an EUV mask according to a second embodiment of the invention;

FIG. 6 schematically depicts another known EUV mask;

FIG. 7a schematically depicts, with a side on view, an EUV mask according to a third embodiment of the invention; and

FIG. 7b schematically depicts, in plan view, the EUV mask according to the third embodiment of the invention.

### DETAILED DESCRIPTION

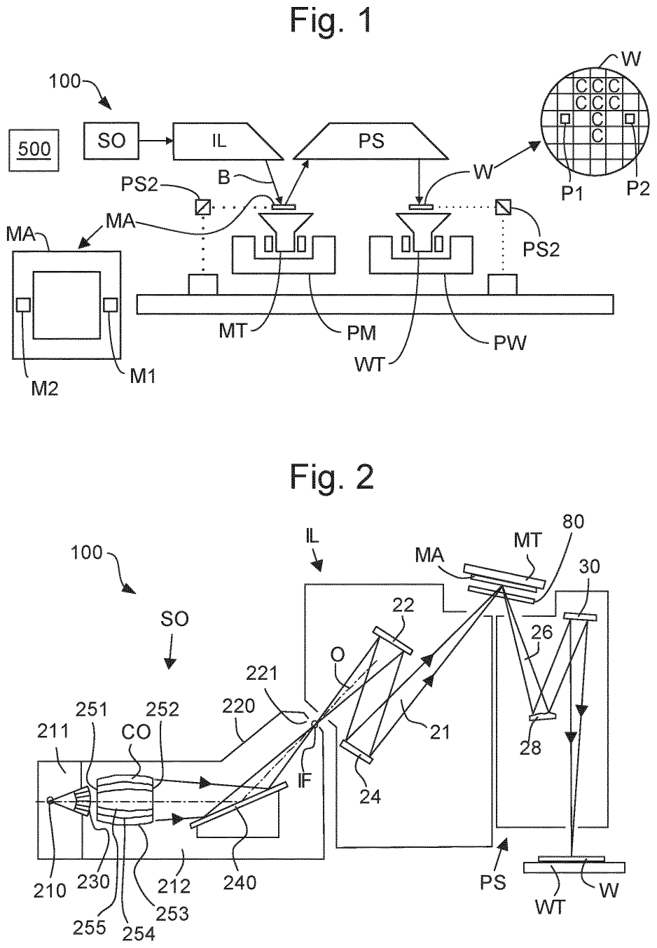

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

The patterning device MA may be transmissive or reflective. Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as sigma-outer and sigma-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

The lithographic apparatus 100 may comprise a dynamic gas lock. The dynamic gas lock comprises a pellicle 80. In an embodiment the dynamic gas lock comprises a hollow part covered by a pellicle 80 located in the intervening space. The hollow part is situated around the path of the radiation. In an embodiment the lithographic apparatus 100 comprises a gas blower configured to flush the inside of the hollow part with a flow of gas. The radiation travels through the pellicle before impinging on the substrate W.

As described above, the lithographic apparatus 100 may comprise a reflective mask for patterning a radiation beam. A known type of reflective mask for EUV radiation is described in EP 1 260 862 A1. The mask comprises a stack of substrates with adjacent layers of the stack having different refractive indices.

Another known type of EUV mask is a reflective absorber based mask. The illuminated surface of this mask comprises regions that absorb incident EUV radiation and regions that reflect incident EUV radiation. When the mask is illuminated by EUV radiation, the EUV radiation that reflects off the mask is patterned in dependence on the pattern of the reflecting and absorbing regions of the mask. A problem with such absorber based masks is that the intensity of the EUV radiation may be substantially reduced by the mask. The intensity of the EUV radiation that illuminates the substrate is therefore low.

An alternative to an absorber based mask is a hard phase shift mask (HPSM). A HPSM differs from an absorber based mask by comprising an illuminated surface that is only designed to reflect EUV radiation. A HPSM does not comprise regions that are designed to absorb EUV radiation. Due to the increased reflectivity of the HPSM, the intensity of the EUV radiation that illuminates the substrate is higher than if an absorber based mask is used.

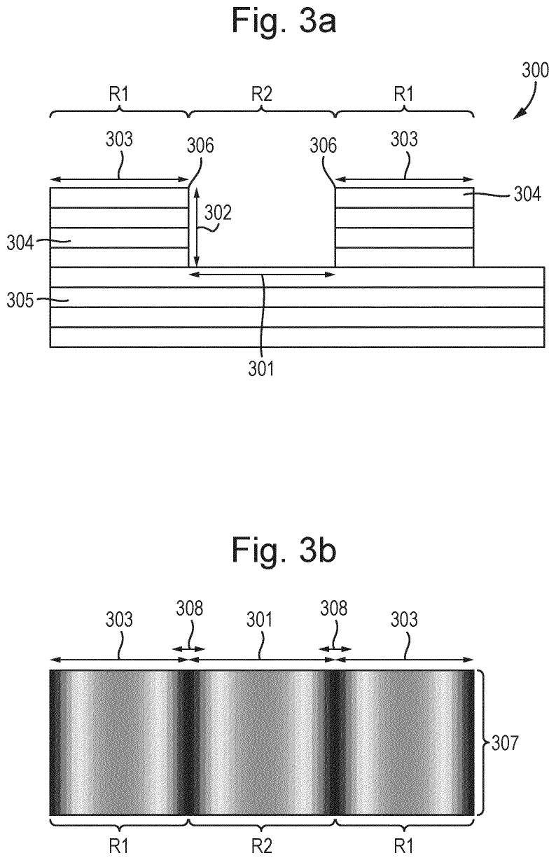

FIG. 3a schematically shows a known HPSM 300 for EUV radiation.

The HPSM 300 is a reflective mask. The upper surface of the mask is illuminated by EUV radiation and the EUV radiation that reflects off the mask is patterned by the mask. The mask comprises a plurality of layers of materials that provide reflective regions. To provide the reflection, each layer of material may have a different refractive index to the layers adjacent to it, in accordance with known techniques for providing a reflective surface for EUV radiation. The HPSM 300 comprises raised structures 304 on a base 305. The raised structures 304 may be made by selectively etching regions in a multilayer structure, with each trough between adjacent raised structures 304 being a region of the multilayer structure that was removed by the etching process. It should be noted that the actual number of layers in the HPSM 300 would typically be a lot larger than that shown in FIG. 3. For example, each raised structure 304 may comprise about 50 layers and the base 305 may comprise about 50 layers.

The upper surfaces of each raised structure 304 define a first reflective region, R1. The upper surfaces of the base 305, that are not covered by a raised structure 304, define a second reflective region, R2. The raised structures 304 extend above the base 305 by a height 302. Each raised structure 304 may have a width 303 and be separated from an adjacent raised structure 304 by the width 301 of each R2. The length of each raised structure 304, i.e. in the direction orthogonal to the height 302 and the width 303, is not shown in FIG. 3a. The height 302 of each raised structure 304, width 303 of each raised structure 304, width 301 of each R2, and length of each raised structure 304 are all design parameters of the HPSM 300 that define the pattern the HPSM 300 imparts on incident EUV radiation. The height 302 is the spatial difference in the reflective surfaces of the HPSM 300. The height 302 may be formed by each raised structure 304 comprising about 10 to 30 substrate layers on the base 305. The required number of substrate layers will depend on the specific properties of the substrate layers. The height 302 may be set such that the EUV radiation that reflects off R1 has a desired phase difference from the EUV radiation that reflects off R2. The desired phase difference may be about 180°, however other phase differences may also be used. The corners 306 define the boundary between R1 and R2.

FIG. 3b shows an aerial image 307 of EUV radiation that has been patterned by reflecting off the HPSM 300. The aerial image 307 comprises dark lines at each boundary between R1 and R2. The critical dimension, CD, of the features that the aerial image 307 may print on a substrate is dependent on the width 308 of the dark lines. The width 303 of R1 and the width 301 of R2 define the separation distances between the dark lines in the aerial image 307. The pitch of features printed on a substrate is thereby dependent on the width 303 of R1 and the width 301 of R2. Due to demagnification in the optics of the lithographic system, the image properties at the HPSM 300 may be about 4 times larger than the image properties at the substrate. It is the image properties at the substrate that define the actual printed features. Accordingly, when the width 308 of the dark lines is 56 nm, the CD of the printed features on a substrate may be 14 nm.

A problem is that the CD of the printed features on a substrate is highly dependent on the pitch of the printed features on a substrate. When the width 303 of R1 and the width 301 of R2 at the HPSM 300 are both about 112 nm, the width 308 of the dark lines at the HPSM 300, that define the CD, may be about 56 nm. However, when the width 303 of R1 and the width 301 of R2 at the HPSM 300 is increased to about 200 nm, the width 308 of the dark lines at the HPSM 300 may increase to about 88 nm and thereby increase the CD of the printed features. This change in CD with the pitch cannot be prevented by varying the design parameters of the known HPSM 300. There is therefore no design freedom that allows the CD variation to be compensated. Another problem with this known HPSM 300 for EUV radiation is that the height 302 required to generate the 180° phase difference inevitably deviates from the imaging performance of a perfectly flat mask. There are also no design parameters that can be freely varied in order to improve aspects of the imaging performance. Due to these problems, the known HPSM 300 is difficult to use with EUV radiation.

The first and second embodiments provide a new HPSM for EUV radiation that improves on the above-described known HPSM 300.

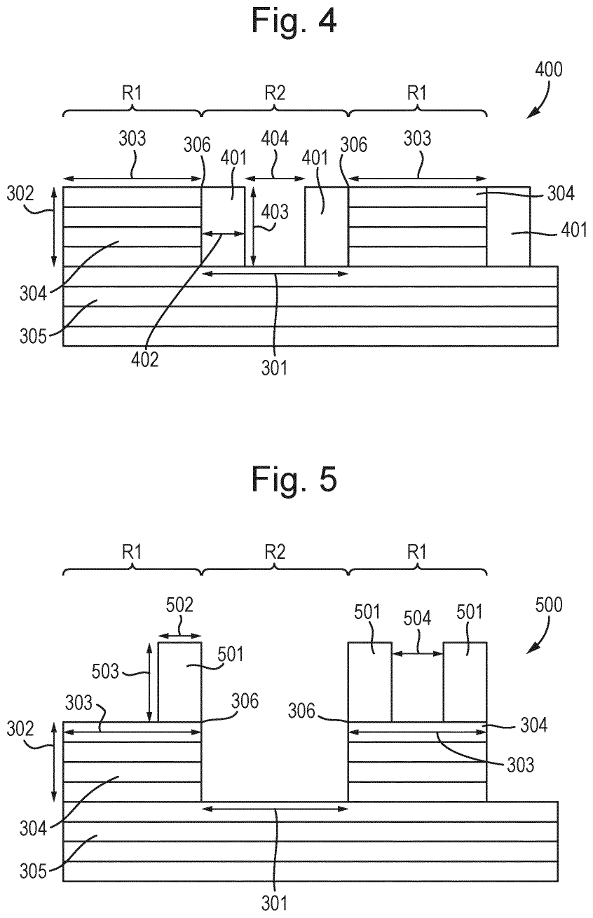

FIG. 4 schematically shows a HPSM 400 for EUV radiation according to a first embodiment.

The HPSM 400 is a reflective mask. The upper surface of the HPSM 400 is illuminated by EUV radiation and the EUV radiation that reflects off the HPSM 400 is patterned by the HPSM 400. The HPSM 400 comprises a plurality of layers of materials that provide reflective regions. To provide the reflection, each layer of material may have a different refractive index to the layers adjacent to it, in accordance with known techniques for providing a reflective surface for EUV radiation.

The HPSM 400 comprises raised structures 304 on a base 305. The raised structures 304 may be made by etching, as described for the known HPSM 300 shown in FIG. 3. It should be noted that the actual number of layers in the HPSM 400 would typically be a lot larger than that shown in FIG. 4. For example, each raised structure 304 may comprise about 50 layers and the base 305 may comprise about 50 layers.

The upper surfaces of each raised structure 304 define a first reflective region, R1. The upper surfaces of the base 305, that are not covered by a raised structure 304, define a second reflective region, R2. The raised structures 304 extend above the base 305 by a height 302. Each raised structure 304 may have a width 303 and be separated from an adjacent raised structure 304 by the width 301 of each R2. The length of each raised structure 304, i.e. in the direction orthogonal to the height 302 and the width 303, is not shown in FIG. 4. The height 302 is the spatial difference in the reflective surfaces of the HPSM 400. The height 302 may be set such that the EUV radiation that reflects off R1 has a 180° phase difference from the EUV radiation that reflects off R2. The corners 306 define the boundary between R1 and R2. R1 and R2 define a patterning surface of the HPSM 400.

The HPSM 400 according to the present embodiment differs from the known HPSM 300 by further comprising waveguide structures 401. The shape of each waveguide structure 401 may be rectangular cuboid. Waveguide structures 401 may be provided on the sides of each raised structure 304. The height 403 of each waveguide structure 401 above the base 305 may be the same as the height 302 of the raised structure 304 above the base 305. The upper surface of each waveguide structure 401 may thereby be co-planar with the upper surface of the raised structure 304. Each waveguide structure 401 has a width 402. There is a separation distance 404 between two waveguide structures 401 that are arranged between adjacent raised structures 304. Due to the combined widths 402 of the waveguide structures 401 between adjacent raised structures 304 being less than the width 301 of each R2, a channel is defined between the waveguide structures 401. The width of the channel is the separation distance 404 and the channel is closed at one end by the surface of the base 305.

The waveguide structures 401 are a waveguide of EUV radiation that the HPSM 400 is illuminated with. The waveguide structures 401 and the channel are a guided structure for modes of the EUV radiation. The formation and shape of such waveguide modes is described in: Investigation of waveguide modes in EUV mask absorbers, by Hazem Mesilhy et al., Journal of Micro/Nanopatterning, Materials, and Metrology, Vol. 20, Issue 2, 021004 (May 2021), https://www.spiedigitallibrary.org/journals/journal-of-micro-nanopatterning-materials-and-metrology/volume-20/issue-2/021004/Investigation-of-waveguide-modes-in-EUV-mask-absorbers/10.1117/1.JMM.20.2.021004.full (as viewed on 21 Feb. 2023).

There are a number of suitable materials for each waveguide structure 401. Preferred materials are Ruthenium and Molybdenum, and other possible materials are listed in Table 1 below.

In the HPSM 400 according to the present embodiment, the design parameters include all of the height 302 of each raised structure 304, width 303 of each raised structure 304, width 301 of each R2, the length of each raised structure 304, the material of each waveguide structure 401, the width 402 of each waveguide structure 401, and the height 403 of each waveguide structure 401. These design parameters of the HPSM 400 define the pattern that the HPSM 400 imparts on EUV radiation. The use of waveguide structures 401 thereby increases the design freedom because the characteristics of the pattern that the HPSM 400 imparts on EUV radiation is dependent on the material and dimensions of each waveguide structure 401.

As described with reference to FIGS. 3A and 3B, the width 303 of each raised structure 304 and the width 301 of R2 define the pitch 303, 301 of the printed features on a substrate W. In the present embodiment, the width 303 of each raised structure 304 and the width 301 of R2 may be set so that the printed features on a substrate W have a user-defined pitch. The user-defined pitch is dependent on the specific design of product that is being manufactured by the lithographic process. The smallest possible value of the user-defined pitch will depend on the numerical aperture, NA, of the lithographic system. The smallest user-defined pitch that is printed at the substrate may be about 28 nm for a 0.33NA system, and be smaller for a lithographic system with a higher NA. The user-defined pitch that is printed at the substrate may be increased to 150 nm, or larger values, to print features with different pitches. The required user-defined pitch may therefore vary over a wide range of values.

The material of each waveguide structure 401 may be selected, and the width 402 and height 403 of each waveguide structure 401 determined, so that for the user-defined pitch of printed features on a substrate W, the aerial image has the desired properties. Accordingly, the use of the waveguide structures 401 allow a desired CD of printed features at the substrate W, that may be 14 nm, to be achieved across a wide range of different pitches of printed features at the substrate W. This is a substantial advantage over the known HPSM 300 shown in FIG. 3 for which there is no way of preventing the CD substantially varying with the pitch.

In the present embodiment, both the width 402 and the height 403 of each waveguide structure 401 are design parameters that may be varied. However, in a preferred implementation of the present embodiment, only the width 402 of each waveguide structure 401 is varied to change the characteristics of the patterned radiation. The waveguide structure 401 height 403 is not varied and is the same as the height 302 of each raised structure 304. This simplifies the manufacture of the HPSM 400.

It should be noted that although the design of the waveguide structures 401 may be determined so as to maintain the same CD across a range of pitches, the use of the waveguide structures 401 may provide other benefits. For example, other advantages may include one or more of improved CD uniformity, reduced pattern shift, improved contrast, and improved CD control. Embodiments also include determining the material and dimensions of the waveguide structures 401 so as to improve any property of the patterned EUV radiation. For example, the material and dimensions of the waveguide structures 401 may be determined so that the patterned EUV radiation has an improved contrast.

Simulations have shown that when the waveguide structures 401 are made from either Ruthenium or Molybdenum, a CD of 14 nm at the substrate can be achieved for all pitches at the substrate between 28 nm and 120 nm. To achieve CD of 14 nm at the substrate across the range of pitches, the width 303 of each raised portion 304, the width 301 of R2, and/or width 402 of each waveguide structure 401 may all be adjusted. The width 303 of each raised portion 304 and the width 301 of R2 may be varied subject to the constraint that the sum of the width 303 of each raised portion 304 and the width 301 of R2 equals twice the separation distance in the aerial image at the HPSM 400 that defines the pitch of the printed features. The CD of 14 nm at the substrate across the range of pitches is achievable with the waveguide structure 401 height 403 being the same as the height 302 of each raised structure 304 at all pitches at the substrate.

Embodiments include each waveguide structure 401 being made from a number of different materials. A non-exhaustive list of suitable materials for each waveguide structure 401 is provided in Table 1. It should be noted that some of the refractive index values in Table 1 have been determined experimentally and the actual refractive index values may vary.

TABLE 1

| Material | Refractive index | Extinction Coefficient |
|---|---|---|
| Rh | 0.875052 | 0.031178 |
| Pd | 0.876122 | 0.046399 |
| Ru | 0.886360 | 0.017064 |
| Pt_f | 0.889330 | 0.057050 |
| Ag | 0.890268 | 0.079382 |
| Pt | 0.890696 | 0.060052 |
| Ir_f | 0.895108 | 0.048783 |
| Au | 0.898789 | 0.051737 |
| PdO | 0.901159 | 0.038871 |
| Os | 0.903523 | 0.043497 |
| Rh_2O_3 | 0.904567 | 0.029894 |
| Ir | 0.904981 | 0.044292 |
| PtO | 0.909029 | 0.048114 |
| Re | 0.914906 | 0.039895 |
| RuO_2 | 0.920737 | 0.021541 |
| Ag_2O | 0.921536 | 0.054481 |
| Mo | 0.923804 | 0.006425 |
| Cd | 0.928150 | 0.054981 |
| OsO_2 | 0.928312 | 0.032690 |
| Mo_2C | 0.928393 | 0.006923 |
| PtO_2 | 0.928911 | 0.036729 |
| SnO_2 | 0.929033 | 0.066966 |
| MoC | 0.929729 | 0.007455 |
| ReO_2 | 0.929899 | 0.032680 |
| Cr_3C_2 | 0.930056 | 0.034098 |
| In | 0.930292 | 0.070033 |
| VN | 0.930303 | 0.027161 |
| Cr_f | 0.930444 | 0.046997 |
| WO_2 | 0.931154 | 0.032875 |
| NbO | 0.932162 | 0.012897 |
| Cr | 0.932453 | 0.038883 |
| Mn | 0.932728 | 0.031774 |
| W | 0.932880 | 0.032968 |
| Hg | 0.933114 | 0.044706 |
| Co | 0.933345 | 0.066208 |
| Nb | 0.933749 | 0.005196 |
| TiN | 0.933888 | 0.019532 |
| VO | 0.933978 | 0.029709 |
| MoO_2 | 0.934096 | 0.016822 |
| Co.75Cr.25 | 0.934260 | 0.057902 |
| Pb | 0.934718 | 0.049113 |
| Co.80Cr.20 | 0.934996 | 0.058687 |
| Cr_2O_3 | 0.936289 | 0.033270 |
| MnO_2 | 0.936749 | 0.029558 |
| TI | 0.936873 | 0.042121 |
| Co_3O_4 | 0.936994 | 0.046870 |
| CoO | 0.937199 | 0.049068 |
| VC | 0.937363 | 0.022639 |
| Cr2O3 | 0.937626 | 0.032571 |
| NbO_2 | 0.938312 | 0.015517 |

The material of each waveguide structure 401 preferably has a refractive index of 0.97 or less. For materials with a higher refractive index, it may not be possible to maintain a constant CD over a wide range of pitches by varying the width 402 of the waveguide structures 401, R1 and R2 alone.

FIG. 5 schematically shows a HPSM 500 for EUV radiation according to a second embodiment. The HPSM 500 of the second embodiment is also a reflective mask with waveguide structures 501.

The HPSM 500 of the second embodiment differs from the HPSM 400 of the first embodiment by the waveguide structures 501 being provided in different locations. The HPSM 500 of the second embodiment may otherwise be the same as the HPSM 400 of the first embodiment. In particular, the raised structures 304 and base 305 may be as described for the first embodiment. R1 and R2 define a patterning surface of the HPSM 500. The waveguide structures 501 of the second embodiment may be made from the same materials as those of the waveguide structures 401 of the first embodiment.

As shown in FIG. 5, in the second embodiment each waveguide structure 501 is located on the upper surface of each raised structure 304. The shape of each waveguide structure 501 may be rectangular cuboid. A waveguide structure 501 may be positioned at each edge of a raised structure 304 so that a side surface of the waveguide structure 501 is coplanar with a side surface of the edge structure 304. Each waveguide structure 501 has a height 503 and width 502. There is a separation distance 504 between adjacent waveguide structures 501 on each raised structure 304.

In the second embodiment, the waveguide structures 501 also define a waveguide for the EUV radiation that the HPSM 500 is illuminated with. The waveguide structures 501 and channels are guided structures for modes of EUV radiation. The modes may form in a channel defined between adjacent waveguide structures 501 on adjacent raised structures 304, with the width of the channel being the width 301 of R2. This may be the main, or only, guided structure if the separation distance 504 a lot larger than the width 301 of R2. However, if the separation distance 504 is similar to or less than the width 301 of R2, modes may also form in each channel defined between adjacent waveguide structures 501 on the same raised structure 304. The width of the channel for these modes is the separation distance 504.

The second embodiment is similar to the first embodiment in that the material, height 503 and width 502 of each waveguide structure 501 are variable design parameters that affect the characteristics of the pattern that the HPSM 500 imparts on EUV radiation. The use of waveguide structures 501 thereby increases the design freedom because the pattern that the HPSM 500 imparts on EUV radiation is dependent on the material and dimensions of each waveguide structure 501. The advantages of the second embodiment are therefore the same as those described of the first embodiment.

For the second embodiment, simulations have shown that when the waveguide structures 501 are made from either Ruthenium or Molybdenum, a CD of 14 nm at the substrate can be achieved for all pitches at the substrate between 28 nm and 120 nm. To achieve CD of 14 nm at the substrate across the range of pitches, the width 303 of each raised portion 304, the width 301 of R2, the width 502 of each waveguide structure 501, and the height 503 of each waveguide structure 501 may all be adjusted. The width 303 of each raised portion 304 and the width 301 of R2 may be varied subject to the constraint that the sum of the width 303 of each raised portion 304 and the width 301 of R2 equals twice the separation distance in the aerial image at the HPSM 500 that defines the pitch of the printed features. The width 502 of each waveguide structure 501 is constrained to the extent that the waveguide structures 501 need to be accommodated on the upper surface of each raised structure 304. The height 501 of each waveguide structure may be less than abut 100 nm.

The HPSMs 400, 500 of both the first and second embodiments are advantageous over known HPSMs 300 due to the increased design freedom provided by the waveguide structures 401, 501. The HPSMs 400, 500 of both the first and second embodiments are also advantageous over known absorber based masks for EUV radiation because they have higher reflectivity. Embodiments thereby reduce the required dose of EUV radiation.

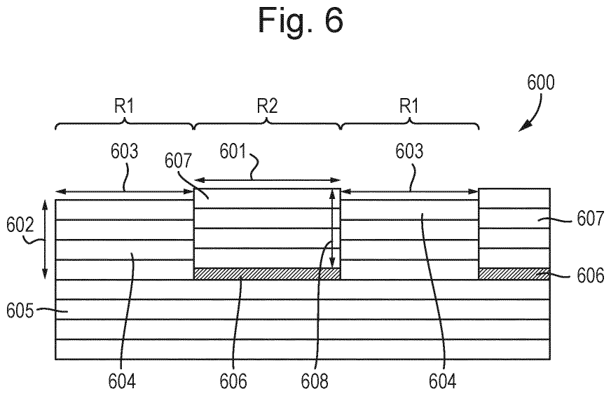

According to a third embodiment, a technique is provided for improving on another known type of HPSM for EUV radiation. FIG. 6 shows a known type of HPSM 600 for EUV radiation that may be referred to as an embedded phase shifter HPSM 600.

The HPSM 600 is a reflective mask. The upper surface of the mask is illuminated by EUV radiation and the EUV radiation that reflects off the mask is patterned by the mask. In a similar manner to the earlier described HPSMs 300, 400, 500 shown in FIGS. 3a, 4 and 5, the HPSM 600 comprises a plurality of layers of materials that provide reflective regions. To provide the reflection, each layer of material may have a different refractive index to the layers adjacent to it, in accordance with known techniques for providing a reflective surface for EUV radiation. It should be noted that the actual number of layers in the HPSM 600 would typically be a lot larger than that shown in FIG. 6.

The HPSM 600 comprises a phase shifting structure 606. The phase shifting structure 606 is covered by a plurality of layers 607 and thereby embedded within the HPSM 600. The phase shifting structure 606 reflects and imparts a phase shift on incident EUV radiation.

The HPSM 600 is similar to the known HPSM 300, as described with reference to FIG. 3a, to the extent that it comprises first reflective regions, R1, and second reflective regions, R2.

Each R1 does not comprise an embedded phase shifting structure 606. Each R1 comprises a plurality of layers 604. The layers 604 of each R1 may extend above a base 605 of the HPSM 600 by a height 602. The height 602 may be formed by about 10 to 30 layers 604 on the base 605. The required number of layers 604 will depend on the specific properties of the layers. The layers 604 may be substantially the same as the layers 304 of the HPSM 300 shown in FIG. 3a. Each R1 has a width 603. The length of each R1, i.e. in the direction orthogonal to the height 602 and the width 603, is not shown in FIG. 6.

Each R2 comprises an embedded phase shifting structure 606. Each R2 comprises a plurality of layers 607. The layers 607 of each R2 may extend above the base 605 of the HPSM 600 by the combined height 608 of the layers 607 and the height of the embedded phase shifting structure 606. The height 608 may be formed by about 10 to 30 layers 607. The required number of layers 607 will depend on the specific properties of the layers 607 and the phase shifting structure 606. The layers 607 may be substantially the same as the layers 304 of the HPSM 300 shown in FIG. 3a. Each R2 has a width 601. The length of each R2, i.e. in the direction orthogonal to the height 608 and the width 601, is not shown in FIG. 6. Each R1 may be separated from an adjacent R1 by the width 601 of an R2.

The height 602 of each R1, width 603 of each R1, height 608 of each R2, width 601 of each R2, length of R1 and R2, and the properties of the phase shifting structure 606 are all design parameters of the HPSM 600 that define the pattern the HPSM 600 imparts on incident EUV radiation.

The design parameters may be set so that the EUV radiation that reflects off R1 has a desired phase difference from the EUV radiation that reflects off R2. The desired phase difference may be about 180°, however other phase differences may also be used.

EUV radiation that has been patterned by reflecting off the HPSM 600 has a similar aerial image to that shown in FIG. 3B. The aerial image comprises dark lines at each boundary between R1 and R2. The critical dimension, CD, of the features that the aerial image may print on a substrate is dependent on the width of the dark lines. The width 603 of R1 and the width 601 of R2 define the separation distances between the dark lines in the aerial image. The pitch of features printed on a substrate is thereby dependent on the width 603 of R1 and the width 601 of R2. Due to demagnification in the optics of the lithographic system, the image properties at the HPSM 600 may be about 4 times larger than the image properties at the substrate W. It is the image properties at the substrate W that define the actual printed features. Accordingly, when the width 308 of the dark lines is 56 nm, the CD of the printed features on a substrate may be 14 nm.

A problem is that the CD of the printed features on a substrate is highly dependent on the pitch of the printed features on a substrate. When the width 603 of R1 and the width 601 of R2 at the HPSM 600 are both about 112 nm, the width of the dark lines at the HPSM 600, that define the CD, may be about 56 nm. However, when the width 603 of R1 and the width 601 of R2 at the HPSM 600 is increased to about 200 nm, the width of the dark lines at the HPSM 600 may increase to about 88 nm and thereby increase the CD of the printed features. This change in CD with the pitch cannot be prevented by varying the design parameters of the known HPSM 600. There is therefore no design freedom that allows the CD variation to be compensated.

The third embodiment provides a new HPSM for EUV radiation that improves on the above-described known HPSM 600.

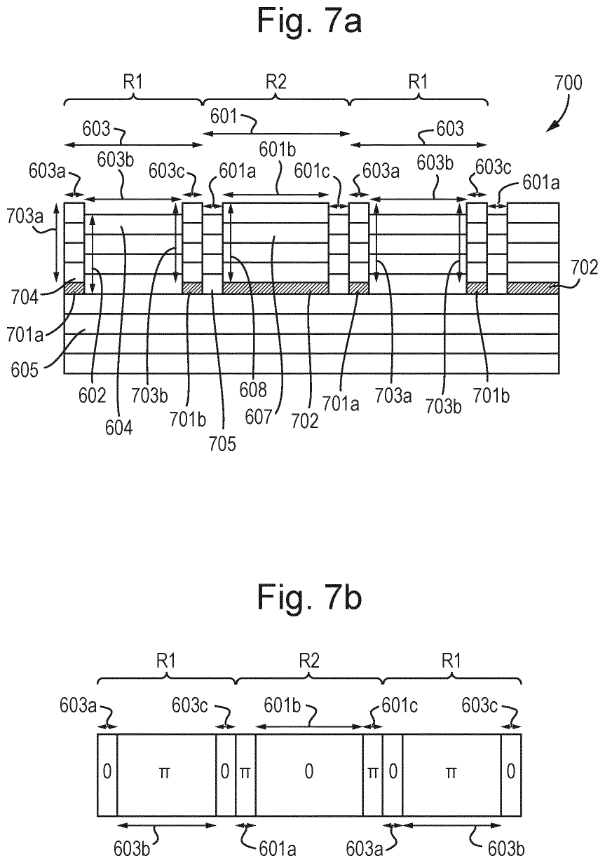

FIG. 7a schematically shows a side on view of a HPSM 700, with an embedded phase shifter, according to a third embodiment. FIG. 7b schematically shows, in plan view, the HPSM 700 according to the third embodiment.

The HPSM 700 is a reflective mask. The upper surface of the HPSM 700 is illuminated by EUV radiation and the EUV radiation that reflects off the HPSM 700 is patterned by the HPSM 700.

The HPSM 700 is similar to the known HPSM 600 described with reference to FIG. 6 in that it comprises first reflective regions, R1, and second reflective regions, R2. Each R1 comprises a plurality of layers 604, 704, the substantial part of which are not arranged above an embedded phase shifting structure 702. Each R2 comprises a plurality of layers 607, 705, the substantial part of which are arranged above an embedded phase shifting structure 702.

The HPSM 700 according to the present embodiment differs from the known HPSM 600 by the ends of each R1 being adapted to include embedded phase shifting structures 701a, 701b, and the ends of each R2 being adapted to not include embedded phase shifting structures.

Each R1 comprises a main region, with a width 603b, that provides the substantial width of R1. The main region may be substantially as described for the known HPSM 600 in FIG. 6 to the extent that a plurality of the same types of layers 604 have the same height 602 and length.

At a first end of each R1, there is a first sub-region of R1 that comprises a plurality of layers 704 on a first sub-resolution phase patch 701a. The first sub-resolution phase patch 701a is an embedded phase shifting structure. The width 603a of the first sub-region of R1 may be a lot less than the width 603 of R1. The height 703a of the layers 704 in the first sub-region of R1 may extend above the base 605 of the HPSM 700 by the combined height 703a of the layers 704 and the height of the embedded phase shifting structure 701a. The height of the first sub-region of R1 is thereby greater than the height 602 of the main region of R1. The length of the first sub-region of R1 may be the same as the length of the main region of R1.

At a second end of each R1, there is a second sub-region of R1 that also comprises a plurality of layers 704 on a second sub-resolution phase patch 701b. The second sub-resolution phase patch 701b is an embedded phase shifting structure. The width 603c of the second sub-region of R1 may be a lot less than the width 603 of R1. The height 703b of the layers 704 in the second sub-region of R1 may extend above the base 605 of the HPSM 700 by the combined height 703b of the layers 704 and the height of the embedded phase shifting structure 701b. The height of the second sub-region of R1 is thereby greater than the height 602 of the main region of R1. The length of the second sub-region of R1 may be the same as the length of the main region of R1.

The first sub-resolution phase patch 701a may be the same as the second sub-resolution phase patch 701b. The first sub-resolution phase patch 701a and the second sub-resolution phase patch 701b may comprise the same type of phase shifting structure 606 used in R2 of the known HPSM 600. The heights and widths 603a, 603c of the first and second sub-regions of R1 may be the same as each other. The heights of the first and second sub-regions of R1 may be the same as the height of the main region of each R2.

Each R2 comprises a main region, with a width 601b, that provides the substantial width of R2. The main region may be substantially as described for the known HPSM 600 in FIG. 6 to the extent that a plurality of the same types of layers 607 are provided on a phase shifting structure 702. The phase shifting structure 702 may be substantially the same as the phase shifting structure 606 in the HPSM 600, except that is has a smaller width 601b. The layers 607 may have the same height 608 and length as the layers in the HPSM 600.

At a first end of each R2, there is a first sub-region of R2 that comprises a plurality of layers 705 that are not provided on the phase shifting structure 702. The width 601a of the first sub-region of R2 may be a lot less than the width 601 of R2. The height of the layers 705 in the first sub-region of R1 may be the same as the height 602 of the layers 604 in the main region of R1. The height of the first sub-region of R2 is thereby less than the height of the main region of R2. The length of the first sub-region of R2 may be the same as the length of the main region of R2.

At a second end of each R2, there is a second sub-region of R2 that comprises a plurality of layers 705 that are not provided on the phase shifting structure 702. The width 601c of the second sub-region of R2 may be a lot less than the width 601 of R2. The height of the layers 705 in the second sub-region of R2 may be the same as the height 602 of the layers 604 in the main region of R1. The height of the second sub-region of R2 is thereby less than the height of the main region of R2. The length of the second sub-region of R2 may be the same as the length of the main region of R2.

The heights and widths 601a, 601c of the first and second sub-regions of R2 may be the same as each other.

In the present embodiment, the HPSM 700 thereby differs from the known HPSM 600 by the sub-regions at the ends of each R1 and R2. The widths 603a, 603c, 601a, 601c of all of the sub-regions may be a lot less than the widths 603, 601 of R1 and R2. For example, when the width 603 of R1 at the HPSM 700 is in a range of about 112 nm to 500 nm, and the width 601 of R2 at the HPSM 700 is in a range of about 112 nm to 500 nm, the width 603a, 603c, 601a, 601c of each sub-region may be in the range 1 nm to 21 nm. Due to their narrow widths, each sub-region may be a sub-resolution part of the HPSM 700. Accordingly, when the HPSM 700 is illuminated with EUV radiation, some of the illuminating light is ejected out of the imaging numerical aperture, NA, due to the presence of the sub-regions, and the different properties of the sub-regions to the main regions. The effect of the sub-regions is to effectively lower the intensity of the printed features. The use of the sub-regions may thereby increase the CD when the HPSM 700 is designed with a small pitch, and also reduce the CD variation with the pitch.

Advantageously, the sub-regions provide the HPSM 700 of the present embodiment with additional design freedom over the known HPSM 600 and this allows at least some of the problems with known HPSMs 600 to be overcome. In particular, the width and height of each sub-region, as well as the type of phase shifting structure used in some of the sub-regions, are all design parameters that can be tuned in order to control the properties of printed features when the HPSM 700 is used in a lithographic apparatus.

Embodiments also include a number of modifications and variations to the techniques described above.

In the above-described first and second embodiments, the shapes of the waveguide structures 410, 501 are rectangular cuboid. Embodiments include alternative shapes of waveguide structure 410, 501. For example, each waveguide structure 401, 501 may alternatively have a triangular cross-section along its length.

The first and second embodiments also include the use of waveguide structures 401 according to the first embodiment in addition to waveguide structures 501 according to the second embodiment. The waveguide structures 401, 501 may thereby be provided both on the upper surfaces of the raised structures 304 and also in the regions between adjacent raised structures 304.

Embodiments also include adapting other types of EUV mask to include waveguide structures. In particular, embodiments include adapting a reflective absorber based mask for EUV radiation to include waveguide structures adjacent to and/or on the absorber material. The material, height and width of each waveguide structure may be varied to alter the characteristics of the pattern that the mask imparts on EUV radiation.

In the third embodiment, the sub-regions of the first reflective region are sub-resolution regions of the first reflective region that have different reflective properties to the main region of the first reflective region. The different reflective properties may be provided by any difference between the sub-regions and the main region, and not necessarily by the use of embedded phase shifting structures. For example, the number and/or type of layers in the sub-regions may be different from the main region. Similarly, the sub-regions of the second reflective region are sub-resolution regions of the second reflective region that have different reflective properties to the main region of the second reflective region. The different reflective properties may be provided by any difference between the sub-regions and the main region, and not necessarily by not using embedded phase shifting structures. For example, the number and/or type of layers in the sub-regions may be different from the main region, or a different type of embedded phase shifting structure may be used.

Although embodiments have been described with reference to masks for EUV radiation, masks according to embodiments may alternatively be made for DUV radiation.

Although embodiments have been described with reference to EUV lithography systems, embodiments may be applied in any type of lithography systems, such as DUV lithography systems.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc., The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described. For example, the various photo resist layers may be replaced by non-photo resist layers that perform the same function.

Embodiments include the following numbered clauses:
1. A mask for patterning radiation in a lithographic apparatus, the mask comprising:
a patterning surface arranged to impart a pattern on radiation; and
waveguide structures arranged on the patterning surface;
wherein the patterning surface comprises:
a first reflective region; and
a second reflective region arranged so that the radiation that reflects off the second reflective region is phase shifted relative to the radiation that reflects off the first reflective region.
2. The mask according to clause 1, wherein:
the first reflective region is a planar surface;
the second reflective region is a planar surface; and
the planes of the first reflective region and the second reflective region are parallel to each other and spaced apart from each other.
3. The mask according to clause 1 or 2, wherein, in use, the radiation that reflects off the second reflective region is phase shifted relative to the radiation that reflects off the first reflective region by about 180°.
4. The mask according to any preceding clause, wherein the waveguide structures define one or more waveguides of the radiation.
5. The mask according to any preceding clause, wherein the waveguide structures are arranged on the first reflective region of the patterning surface.
6. The mask according to any preceding clause, wherein the waveguide structures are arranged on the second reflective region of the patterning surface.
7. The mask according to any preceding clause, wherein the waveguide structures have a refractive index of 0.97 or less.
8. The mask according to any preceding clause, wherein the waveguide structures comprise Ruthenium and/or Molybdenum.
9. The mask according to any preceding clause, wherein the mask comprises a multilayer stack of substrates; and the first reflective region comprises more layers of substrates than the second reflective region.
10. The mask according to any preceding clause, wherein the mask is arranged to pattern EUV radiation in an EUV lithographic apparatus.
11. A lithographic apparatus comprising the mask according to any preceding clause.
12. A method of designing a reflective mask for patterning radiation in a lithographic apparatus,
wherein the mask comprises first and second reflective regions for imparting different phase shifts on illuminating radiation and the mask comprises waveguide structures on the first and/or second reflective regions, the method comprising:
determining a combined width of the first and second reflective regions of the mask in dependence on a user-defined pitch of features to be printed by radiation patterned by the mask;
determining the material and location of each waveguide structure; and
determining the dimensions of each waveguide structure, the width of the first reflective region and the width of the second reflective region such that the radiation patterned by the mask has a desired characteristic.
13. The method according to clause 12, wherein the desired characteristic is a desired critical dimension.
14. The method according to clause 12 or 13, wherein the mask is according to any of clauses 1 to 10.
15. A method for performing lithography, the method comprising projecting a radiation beam through a low pressure environment onto a substrate in an exposure operation;
wherein the radiation beam reflects off a mask located in the low pressure environment; and
the mask is according to any of clauses 1 to 10.
16. The method according to clause 15, wherein the radiation beam is an EUV radiation beam.
17. A mask for patterning radiation in a lithographic apparatus, the mask comprising a patterning surface arranged to impart a pattern on radiation;
wherein:
the patterning surface comprises a first reflective region and a second reflective region;
the second reflective region comprises an embedded phase shifting structure that is arranged so that the radiation that reflects off the second reflective region is phase shifted relative to the radiation that reflects off the first reflective region;
the first reflective region comprises a main region and at least one sub-region at an end of the first reflective region;
the at least one sub-region of the first reflective region has different reflective properties to the main region of the first reflective region;
the second reflective region comprises a main region and at least one sub-region at an end of the second reflective region; and
the at least one sub-region of the second reflective region has different reflective properties to the main region of the second reflective region.
18. The mask according to clause 17, wherein:
the first reflective region comprises a first sub-region at a first end of the first reflective region and a second sub-region at a second end of the first reflective region; and
each sub-region of the first reflective region has different reflective properties to the main region of the first reflective region.
19. The mask according to clause 17 or 18, wherein:
the second reflective region comprises a first sub-region at a first end of the second reflective region and a second sub-region at a second end of the second reflective region; and
each sub-region of the second reflective region has different reflective properties to the main region of the second reflective region.
20. The mask according to any of clauses 17 to 19, wherein the main region of the first reflective region provides the substantial part of the first reflective region.
21. The mask according to any of clauses 17 to 20, wherein the main region of the second reflective region provides the substantial part of the second reflective region.
22. The mask according to any of clauses 17 to 21, wherein each sub-region of the first reflective region comprises a phase shifting structure.
23. The mask according to any of clauses 17 to 22, wherein each sub-region is a sub-resolution region of the mask.
24. The mask according to any of clauses 17 to 23, wherein the mask is arranged to pattern EUV radiation in an EUV lithographic apparatus.
25. A lithographic apparatus comprising the mask according to any of clauses 17 to 24.
26. A method for performing lithography, the method comprising projecting a radiation beam through a low pressure environment onto a substrate in an exposure operation;
wherein the radiation beam reflects off a mask located in the low pressure environment; and the mask is according to any of clauses 17 to 24.
27. The method according to clause 26, wherein the radiation beam is an EUV radiation beam.

The descriptions above are intended to be illustrative, not limiting. Thus it will be apparent to one skilled in the art that modifications may be made to the invention as described without departing from the scope of the claims set out below.

1-27. (canceled)

28. A mask for patterning radiation in a lithographic apparatus, the mask comprising:
a patterning surface arranged to impart a pattern on radiation; and
waveguide structures arranged on the patterning surface,
wherein the patterning surface comprises first and second reflective regions arranged so that radiation that reflects off the second reflective region is phase shifted relative to radiation that reflects off the first reflective region.

29. The mask of claim 28, wherein:
the first and second reflective regions are planar surfaces; and
the planar surfaces of the first reflective region and the second reflective region are parallel to each other and spaced apart from each other.

30. The mask of claim 28, wherein, in use, the radiation that reflects off the second reflective region is phase shifted relative to the radiation that reflects off the first reflective region by about 180°.

31. The mask of claim 28, wherein the waveguide structures define one or more waveguides for the radiation.

32. The mask of claim 28, wherein the waveguide structures are arranged on the first reflective region of the patterning surface.

33. The mask of claim 28, wherein the waveguide structures are arranged on the second reflective region of the patterning surface.

34. The mask of claim 28, wherein the waveguide structures have a refractive index of 0.97 or less.

35. The mask of claim 28, wherein the waveguide structures comprise Ruthenium and/or Molybdenum.

36. The mask of claim 28, wherein:
the mask comprises a multilayer stack of substrates; and
the first reflective region comprises more layers of substrates than the second reflective region.

37. A method of designing a reflective mask for patterning radiation in a lithographic apparatus, the mask comprising first and second reflective regions for imparting different phase shifts on illuminating radiation and waveguide structures on the first and/or second reflective regions, the method comprising:
determining a combined width of the first and second reflective regions of the mask in dependence on a user-defined pitch of features to be printed by radiation patterned by the mask;
determining material and location of each waveguide structure; and
determining the dimensions of each of the waveguide structures, the width of the first reflective region and the width of the second reflective region such that the radiation patterned by the mask has a desired characteristic.

38. The method of claim 37, wherein the desired characteristic is a desired critical dimension.

39. A method for performing lithography, the method comprising:
projecting a radiation beam through a low pressure environment onto a substrate in an exposure operation;
wherein the radiation beam reflects off the mask according to claim 28 that is located in the low pressure environment.

40. A mask for patterning radiation in a lithographic apparatus, the mask comprising:
a patterning surface arranged to impart a pattern on radiation and comprising first and second reflective regions,
wherein the second reflective region comprises an embedded phase shifting structure that is arranged so that radiation that reflects off the second reflective region is phase shifted relative to radiation that reflects off the first reflective region,
wherein the first reflective region comprises a main region and at least one sub-region at an end of the first reflective region, the at least one sub-region of the first reflective region comprising different reflective properties compared to the main region of the first reflective region, and
wherein the second reflective region comprises a main region and at least one sub-region at an end of the second reflective region, the at least one sub-region of the second reflective region comprising different reflective properties compared to the main region of the second reflective region.

41. The mask of claim 40, wherein:
the first reflective region comprises a first sub-region at a first end of the first reflective region and a second sub-region at a second end of the first reflective region; and
each sub-region of the first reflective region has different reflective properties compared to the main region of the first reflective region.

42. The mask of claim 40, wherein:
the second reflective region comprises a first sub-region at a first end of the second reflective region and a second sub-region at a second end of the second reflective region; and
each sub-region of the second reflective region has different reflective properties compared to the main region of the second reflective region.

43. The mask of claim 40, wherein the main region of the first reflective region provides the substantial part of the first reflective region.

44. The mask of claim 40, wherein the main region of the second reflective region provides the substantial part of the second reflective region.

45. The mask of claim 40, wherein each sub-region of the first reflective region comprises a phase shifting structure.

46. The mask of claim 40, wherein each sub-region is a sub-resolution region of the mask.

47. A method for performing lithography, the method comprising:
projecting a radiation beam through a low pressure environment onto a substrate in an exposure operation;
wherein the radiation beam reflects off the mask according to claim 40 that is located in the low pressure environment.
